(19) United States
(12) Patent Application Publication
(10) Pub. No.: US 2002/0009671 A1
(43) Pub. Date: Jan. 24, 2002

(54) POSITIVE-WORKING IR-SENSITIVE MIXTURE

(76) Inventors: WILLI-KURT GRIES, MAINZ-KASTEL (DE); JOERG JUNG, FLOERSHEIM (DE)

Correspondence Address: FOLEY & LARDNER, 3000 K STREET NW SUITE 500, PO BOX 25696, WASHINGTON, DC, 200078696

(21) Appl. No.: 09/149,217

(22) Filed: Sep. 8, 1998

(30) Foreign Application Priority Data
Sep. 8, 1997 (DE) 197 39 302.0

(51) Int. Cl. G03F 7/038

(52) U.S. Cl. 430/273.1; 430/270.1; 430/278.1; 430/302

(57) ABSTRACT

The invention relates to a positive-working IR-sensitive mixture which contains a binder which is insoluble in water but soluble or at least swellable in aqueous alkali and carbon black particles dispersed in such a binder, the dispersed carbon black particles forming the radiation-sensitive component essential for the imagewise differentiation. It furthermore relates to a recording material having a substrate and a radiation-sensitive layer comprising this mixture. If desired, a top layer is also present on the radiation-sensitive layer. Even without a top layer, the material is insensitive to white light. By imagewise exposure to IR radiation, especially from IR lasers or IR laser diodes, and subsequent development with an aqueous alkaline developer, there is produced from the recording material a printing plate for offset printing.

### BACKGROUND OF THE INVENTION

1. Field of the Invention

The present invention relates to a positive-working IR-sensitive mixture, a recording material having a substrate and a layer comprising this mixture; and a process for the production of a printing plate comprising the recording material.

2. Description of the Related Art

Conventionally, recording materials whose radiation-sensitive layer is sensitive in the ultraviolet and/or visible range are used for the production of printing plates for offset printing. The layer is recorded on through a photographic negative using radiation of the appropriate wavelength and is then developed. More recent processes manage without such a photographic negative. The recording is then effected by means of laser beams from digitally controlled lasers (known as “computer-to-plate” process). Lasers which emit radiation in the range of visible light are, however, relatively expensive and require special recording materials. See, for example, EP-A 0 573 805 (=CA-A 2 097 038) and EP-A 0 704 764.

On the other hand, infrared lasers, in particular infrared laser diodes, are substantially more economical. Recording materials which are sensitized in the IR range, i.e. in the range from about 700 to 1100 nm, are used for this purpose. Many of these IR-sensitized materials have the further advantage that they are not sensitive in the ultraviolet and visible range (referred to below as UV/VIS) and can consequently be processed in daylight or normal white artificial light. Examples of these are found in DE-A 25 12 038 (=GB-A 1 489 308), WO 90/12342 and EP-A 0 562 952, 0 580 393,and 0 773 112.

Other materials are known which are sensitized both in the UV/VIS and in the IR range (EP-A 0 625 728 and 0 672 954). The radiation-sensitive layer of these materials contains an IR absorber, a resol, a novolak, and a compound which produces an acid on exposure. The acid formed photochemically during the imagewise exposure results in crosslinking of resol and novolak during subsequent heating of the recording material. The unexposed parts of the layer can then be selectively removed by means of an aqueous alkaline developer solution.

The recording material according to WO 96/20429 comprises a layer which contains an IR absorber and a 1,2-naphthoquinone-2-diazidesulfonic acid ester or -carboxylic acid ester and a phenol resin or an ester of 1,2-naphthoquinone-2-diazidesulfonic acid or -carboxylic acid and a phenol resin. The layer is exposed uniformly to UV radiation and then imagewise to IR laser beams. As a result of the action of the IR radiation, specific parts of the initially solubilized layer become insoluble again. This is therefore a negative-working system. The processing of the material is thus relatively complicated.

Finally, the nonprior published DE-A 197 12 323 describes a thermally recordable material whose radiation-sensitive layer contains an IR absorber (such as carbon black), a UV-sensitive diazo compound, and a binder. Consequently, the material can be handled only in yellow safety light. The sensitivity to white light can be eliminated by adding a top layer. However, this requires an additional production step.

### SUMMARY OF THE INVENTION

There is therefore a need for mixtures for use in recording materials which can be recorded on using IR radiation but which are insensitive to UV/VIS radiation. They should be sensitized over the entire IR range but should be capable of being processed under normal illumination, so that the yellow safety illumination customary to date becomes superfluous. As in the case of conventional printing plates, aqueous alkaline solutions should be sufficient for development.

In accordance with those objectives, there has been provided a positive-working infrared-sensitive mixture which includes: (i) a binder which is insoluble in water but soluble or at least swellable in aqueous alkali; and (ii) carbon black particles dispersed in the binder, wherein the dispersed carbon back particles comprise a radiation-sensitive component for imagewise differentiation.

In accordance with those objectives, there has been provided a recording material having a substrate and a radiation-sensitive layer, wherein the layer comprises a mixture as discussed above.

In accordance with the objectives, there has been provided a process for the production of a printing plate for offset printing, comprising exposing a recording material as discussed above imagewise to infrared radiation, and then developing the exposed material in an aqueous alkaline developer at a temperature of from 20 to 40° C.

Further objects, features and advantages of the invention will become apparent from the detailed description that follows.

### DETAILED DESCRIPTION OF PREFERRED EMBODIMENTS

The present invention is directed to a positive-working IR-sensitive mixture which contains a binder which is insoluble in water but soluble or at least swellable in aqueous alkali and carbon black particles dispersed in such a binder. However, the mixture preferably contains no components which, under the action of UV/VIS radiation, cause a substantial change in the solubility of the mixture, or of the layer produced therefrom, in aqueous alkali. That means, UV/VIS radiation does not cause an imagewise differentiation.

The present invention furthermore relates to a recording material having a substrate and a positive-working, IR-sensitive layer comprising this mixture. The dispersed carbon black particles form therein the radiation-sensitive component essential for the imagewise differentiation. In this context, “imagewise differentiation” means that the dissolution rate of the exposed parts in an aqueous alkaline developer is so far above that of the unexposed parts that the exposed parts are completely removed during development whereas the unexposed parts remain virtually intact. Further components which give rise to imagewise differentiation are consequently not necessary in the mixture. In particular, no UV/VIS-sensitive components need to be present. Here—as generally customary—“IR-sensitive” is intended to be understood as meaning that the mixture or the layer formed therefrom is sensitive to radiation having a wavelength of from 700 to 1100 nm.

Any desired carbon black particles can be used. Carbon black pigments, for example those according to WO 96/20429, (herein incorporated by reference in its entirety) are suitable in particular as IR-absorbing components since they absorb over a broad IR wavelength range. It is therefore possible to use both Nd-YAG lasers, which operate at a wavelength of 1064 nm, and also economic laser diodes, which operate at 830 nm. Carbon black particles having a mean primary particle diameter of from 10 to 220 nm, particularly preferably from 35 to 110 nm and in particular from45 to 100 nm are preferred. According to DIN 53206the term “primary particles” means very small particles (individual particles) of which pulverulent substances are composed. They are detectable as individual entities under the electron microscope. Suitable carbon blacks are in particular flame, furnace, gas, or channel blacks and those which are prepared by the thermal black process or the acetylene black process (cf. company publication of Degussa AG “What is carbon black”). The surface area of the carbon black particles determined by the Brunauer, Emmett and Teller method (“BET surface area”) is in general from 5 to 500 m² per gram, preferably from 8 to 250 m² per gram. Particularly suitable carbon blacks are those which have a dibutyl phthalate absorption of more than 30 ml per 100 g, in particular more than 40 ml per 100 g, and those which are oxidized on their surface, with the result that acidic units form. Neutral carbon blacks are also suitable, as are carbon blacks having basic groups on the surface.

The dispersing of the carbon black particles with the binder can be carried out in generally known apparatuses, in any desired manner. For example, the mixture of pigment and binder can first be dispersed in a dissolver and then finely dispersed in a ball mill. Any desired solvents can be useful. The organic solvents used may be different from the actual coating solvents to be used but are preferably identical. Particularly suitable solvents are propylene glycol monomethyl ether (PGME), propylene glycol monomethyl ether acetate (PGMEA), ethyl lactate, butanone, γ-butyrolactone, tetrahydrofuran, and mixtures thereof. The stability of the dispersions thus produced can be further improved in some cases by adding surfactants and/or thickeners. Surfactants and thickeners soluble in aqueous alkaline solutions are particularly preferred. The amount of the carbon black particles is in general from 1 to 50% by weight, preferably from 3 to 15% by weight, based in each case on the total weight of the nonvolatile components of the mixture.

The IR radiation-sensitive mixture or the layer formed therefrom contains at least one binder, generally a polymeric binder. Any desired binder can be used. Binders having acidic groups whose pKₐ is less than 13, and in particular is in a PKₐ range of from 2.5 to 12, are particularly suitable for ensuring that the layer is soluble or swellable in aqueous alkali. Examples of these are polycondensates, as obtained in the reaction of phenols or sulfamoyl- or carbamoyl-substituted aromatics with aldehydes or ketones. In this context, “phenols” may also be substituted phenols, such as resorcinol, cresol, xylenol or trimethylphenol, in addition to phenol. The aldehyde is preferably formaldehyde. Novolaks, especially cresol/formaldehyde and cresol/xylenol/formaldehyde novolaks, are particularly suitable polycondensates. Reaction products of diisocyanates with diols or diamines are also suitable provided that they have acidic units of the stated type. Polymers having units of vinylaromatics, N-aryl (meth)acrylamides or aryl(meth)acrylates may furthermore be mentioned, these units each also having one or more carboxyl groups, phenolic hydroxyl groups, sulfamoyl groups or carbamoyl groups. Specific examples are polymers having units of 2-hydroxyphenyl (meth)-acryl ate, of N-(4-hydroxyphenyl) (meth)acrylamide, of N-(4-sulfamoylphenyl) (meth)acrylamide, of N-(4-hydroxy-3,5-dimethylbenzyl) (meth)acrylamide, of 4-hydroxystyrene, or of hydroxyphenylmaleimide.

The polymers may additionally contain units of other monomers which have no acidic groups. These include, for example, units of olefins or vinyl-aromatics, methyl (meth)acrylate, phenyl (meth)acrylate, benzyl (meth)acrylate, methacrylamide or acrylonitrile. The term “(meth)acrylate” stands for “acrylate and/or methacrylate”. The same applies to “(meth)acrylamide” and “(meth)acrylic acid”.

The amount of the binder is in general from 50 to 99% by weight, preferably from 85 to 97% by weight, based in each case on the total weight of the non-volatile components of the layer. In a particularly preferred embodiment, the binder comprises at least 50% by weight, in particular 80% by weight or more, of novolak, based on the total weight of binders.

In a preferred embodiment, the mixture or the radiation-sensitive layer also contains one or more compounds which improve the resistance to the developer and/or processing chemicals (these include the fountain solution, plate cleaner, etc. used during printing), and/or compounds which control the rate of development. For example, ketones (especially diaryl ketones, such as benzophenone and naphth-2-yl phenyl ketone), quinones (especially phenanthroquinone), indenones (especially 2,3-diphenylindenone), chromen-4-ones (especially 3-phenylchromen-4-one and α and β-naphthoflavone), xanthone, Meldrum's acid, sulfones (especially diphenyl sulfone) and sulfonic acid esters (especially phenyl paratoluenesulfonate and phenyl naphthalene- 1-sulfonate) are suitable for increasing the resistance to aqueous alkaline developers. In addition, polymeric compounds, such as polyphthalaldehyde, polyethylene glycol, polypropylene glycol, poly(4-hydroxystyrene) having protected hydroxyl groups, poly(meth)acrylate or nitrocellulose, may also be used. The amount of these compounds is an effective amount to give desired results and in general is from 0.5 to 20.0% by weight, preferably from 1.0 to 10.0% by weight, based in each case on the total weight of the non-volatile components of the mixture or of the layer.

In general, compounds which are better or more rapidly soluble than the binder itself in the aqueous alkaline developer are used for controlling the rate of development. Such compounds are, for example, polyhydroxyaromatics (especially 2,4-dihydroxybenzophenone, 2,3,4-trihydroxybenzophenone, 2,3,4,4′-tetra-hydroxybenzophenone and pyrogallol), aromatic mono-, di- or polycarboxylic acids (especially benzoic acid, phthalic acid, terephthalic acid, benzene-1,2,4-tricarboxylic acid=trimellitic acid, benzene-1,3,5-tricarboxylic acid=trimesic acid, salicylic acid, 4-hydroxybenzoic acid, 3,4,5-trihydroxybenzoic acid=gallic acid and 3,4,5-trimethoxybenzoic acid), aliphatic di- or polycarboxylic acids (especially oxalic acid, malonic acid and succinic acid), sulfonic acids (especially para-toluenesulfonic acid and camphorsulfonic acid) and compounds having N—H acidic groups (especially phthalimide and saccharin). Polymeric compounds, too, can control the rate of development, in particular those having an acid number of more than 100. Copolymers having a sufficient number of(meth)acrylic acid units and partially hydrolyzed polyvinyl acetals whose free, unacetalated hydroxyl groups are modified with acid-containing radicals may be mentioned here. The amount of these compounds is an effective amount to give desired results and in general from 0.5 to 20.0% by weight, preferably from 1.0 to 10.0% by weight, based in each case on the total weight of the non-volatile components of the mixture or of the layer.

The radiation-sensitive layer may also contain minor or customary amounts of further additives generally customary in such layers. These include dyes and surfactants (preferably fluorine-containing surfactants or silicone surfactants). In addition to the carbon black particles, the layer may also contain further IR absorbers, such as squarylium, cyanine, merocyanine, or pyrylium compounds. Compounds which form an acid under the action of IR radiation may also be present. These include, for example, para-quinonediiminium dyes, such as ®Cyasorb IR-165 from American Cyanamid. However, the further IR absorbers are not present in amounts such that they would be capable alone of effecting sufficient imagewise differentiation. Differentiation is regarded as “sufficient”, when after development a clear image is obtained. Their amount should not be more than 40% by weight, preferably not more than 20% by weight, based in each case on the total weight of the carbon black particles.

The substrate in the recording material according to the invention can be any desired substrate and is preferably in a foil or sheet of aluminum or of an aluminum alloy or a laminate of an aluminum foil and a polyester film. The aluminum surface is preferably mechanically and/or electrochemically roughened and anodically oxidized. It may also have been hydrophilized with a suitable, generally polymeric compound. Compounds having phosphonic acid or phosphonate units, in particular polyvinylphosphonic acid, are suitable for this purpose. The actual roughening may furthermore be preceded by degreasing, optionally also further mechanical and/or chemical roughening.

To form a recording material, a solution of the IR radiation-sensitive mixture described is applied to a substrate and dried. This may be accomplished in any desired manner. The abovementioned, generally customary organic solvents, as may also be used for dispersing the carbon black, are suitable as coating solvents. After drying, the IR radiation-sensitive layer generally has a layer weight of from 0.5 to 5.0 g/m², preferably from 1.0 to 3.0 g/m², corresponding to about 0.5-5.0 μm, preferably about 1.0-3.0 μm.

To improve the scratch resistance of the recording material and to avoid parts of the layer being removed by centrifugal force during the imagewise exposure, a top layer may also be applied to the IR-sensitive layer. Any desired top layer can be used. The top layer generally comprises water-soluble polymeric binders, such as polyvinyl alcohol, polyvinylpyrrolidone, partially hydrolyzed polyvinyl acetates, gelatine, carbohydrates, or hydroxyethylcellulose. The top layer may be transparent to IR and UV/VIS radiation. A corresponding recording material having a UV/VIS-opaque top layer can also be used and is described in DE-A 197 39 299 filed Sep. 8, 1997 (=U.S. application Ser. No. ______, filed concurrently herewith, Attorney Docket No. 34607/146) herein incorporated by reference. The top layer can be produced from an aqueous solution or dispersion which may also contain small amounts of organic solvents, i.e. less than 5% by weight based on the total weight of the coating solvent for the top layer. The thickness of the top layer is in general up to 5 μm, preferably 0.1 to 3.0 μm. Moreover, the recording material according to the invention generally contains no further layers.

The present invention also relates to a process for the production of a printing plate for offset printing from the recording material according to the invention. Any desired exposing and developing methods can be used in the process. For example, the recording material is first exposed imagewise to infrared radiation and then developed in a conventional aqueous alkaline developer at a temperature of from20 to40° C. During the development, any water-soluble top layer present is also removed. In a further embodiment of the process according to the invention, the top layer is removed with water before or after the recording by means of IR radiation, but before the development. Outer- or inner-drum exposure units having laser diodes (emission maximum 830 nm) or Nd-YAG lasers (emission maximum 1064 nm) are particularly suitable for recording by means of infrared radiation. The radiant energy required for imagewise differentiation is chosen so that a fog-free image is obtained after development. This means that the layer has been completely removed in the exposed parts after the development. During exposure, only a small amount, if any at all, of the IR-sensitive layer is removed. The recording material according to the invention is also distinguished by a relatively large “exposure latitude”. This means that it is not “overexposed” until it is exposed to very high energy.

For positive plates, conventional developers can generally be used for the development. Silicate-based developers which have a ratio of SiO₂ to alkali metal oxide of at least 1 are preferred. This ensures that the alumina layer of the substrate is not damaged. Preferred alkali metal oxides are Na₂O and K₂O and mixtures thereof. In addition to alkali metal silicates, the developer may contain further components such as buffer substances, complexing agents, antifoams, organic solvents in small amounts, corrosion inhibitors, dyes, surfactants and/or hydrotropic agents. The development is generally effected in mechanical processing lines.

To increase the resistance of the produced printing plate and hence to increase the possible length of print run, said printing plate can be briefly heated to elevated temperatures (“baking”). This also increases the resistance of the printing plate to developers, correction compositions and UV-curable printing inks. Such a thermal aftertreatment is described, inter alia, in DE-A 14 47 963 (=GB-A 1 154 749), both hereby incorporated by reference in their entirety.

The following examples are intended to illustrate the subject of the invention without limiting it. Percentages therein are percentages by weight and ratios are weight ratios, unless stated otherwise. “pbw” stands for part(s) by weight.

### EXAMPLE 1

A coating dispersion was prepared from

11.00 pbw of carbon black dispersion having the composition stated below,

12.00 pbw of cresol/xylenol/formaldehyde novolak (®Alnovol SPN 400 from Vianova Resins GmbH, 45.3% strength in propylene glycol monomethyl ether acetate),

0.01 pbw silicone oil for improving the surface structure,

51.99 pbw of propylene glycol monomethyl ether (PGME) and

25.00 pbw of tetrahydrofuran.

The carbon black dispersion comprised

10.0 pbw of carbon black (®Printex 25),

59.99 pbw of cresol/xylenol/formaldehyde novolak (®Alnovol SPN 400, 45.3% strength in PGMEA),

30.0 pbw of PGME and

0.01 pbw of silicone oil.

The coating solution was applied by spin-coating to an aluminum foil roughened in hydrochloric acid, anodized in sulfuric acid and hydrophilized with polyvinylphosphonic acid. After drying for 2 min at 100° C., the layer thickness was 2 μm.

The thermal recording was then carried out using a digital halftone copy in an outer-drum exposure unit with an IR laser diode strip (emission maximum: 830 nm; power of each individual diode: 40 mW, write speed: 1 m/s; beam width: 10 μm). Exposure was carried out using an energy of 400 mJ/cm².

The development was carried out in a conventional processing line at a throughput speed of1.0 m/min at a temperature of 25° C. using an aqueous potassium silicate developer which contained K₂SiO₃(normality: 0.8 mol/l in water) and 0.2% by weight of O,O′-biscarboxymethylpolyethylene glycol 1000 and 0.4% by weight of pelargonic acid. A dot resolution of from 1 to 99% of a 60-line screen was achieved with both recording materials. The image background was fog-free. It was possible to produce more than 40,000 satisfactory prints using the offset printing plates thus produced.

### EXAMPLE 2

An aluminum foil (as described in Example 1) was coated by spin-coating with a dispersion of

11.00 pbw of cresol/xylenol/formaldehyde novolak (®Alnovol SPN400, 45.3% strength in PGMEA),

0.35 pbw of 2,3,4-trihydroxybenzophenone,

11.00 pbw of carbon black dispersion (as in Example 1),

0.01 pbw of silicone oil,

52.64 pbw of PGME and

25.00 pbw of tetrahydrofuran.

In further experiments, the 0.35pbw of 2,3,4-trihydroxybenzophenone were replaced by the same amount of 3,4,5-trimethoxybenzoic acid, by 0.8 times the amount of saccharin or by 1.35 times the amount of phthalimide. After drying for 2 min at 100° C., the layer weight was in each case 2 g/m². The recording materials thus produced were then thermally recorded on according to Example 1 by means of a digital halftone copy. A radiant energy as low as 200 mJ/cm² was sufficient for obtaining a fog-free image. However, the resistance to the developer was slightly lower than in Example 1. The dot resolution and the printing properties of the four different printing plate thus obtained were comparable with that of Example 1. The points had been slightly more strongly attacked by the developer so that the tonal range was from 3 to 99% of the 60-line screen.

### EXAMPLE 3

An aluminum foil (as described in Example 1) was coated by spin-coating with a dispersion of

9.70 pbw of cresol/xylenol/formaldehyde novolak (®Alnovol SPN 400, 45.3% strength in PGMEA),

0.80 pbw of poly(4-hydroxystyrene) having an M_{W} of from 4000 to 6000 and an Mₙ of from 2100 to 3100 (®Maruka Lyncur M, type S-2, from Maruzen Petrochemical Co., Ltd.),

8.00 pbw of carbon black dispersion (as in Example 1),

0.01 pbw of silicone oil,

49.99 pbw of PGME and

31.50 pbw of tetrahydrofuran.

The thermal recording was then carried out as in Example 1. The radiant energy was 150 mJ/cm². In this way, a fog-free image was obtained. The dot circumference and printing properties of the printing plate thus obtained were virtually identical to that of Example 2.

### EXAMPLE 4

A coating dispersion was prepared from

8.60 pbw of carbon black dispersion having the composition stated below,

9.60 pbw of cresol/xylenol/formaldehyde novolak (®Alnovol SPN 400, 45.3% strength in PGMEA),

0.40 pbw of polymethacrylate resin (®Elvacite 2013 from DuPont de Nemours),

1.40 pbw of poly(4-hydroxystyrene) (®Maruka Lyncur M, type S-2),

0.01 pbw of silicone oil,

49.99 pbw of PGME and

30.00 pbw of tetrahydrofuran.

The carbon black dispersion comprised

5.00 pbw of carbon black (special black 250 from Degussa AG),

66.00 pbw of cresol/xylenol/formaldehyde novolak (®Alnovol SPN 400, 45.3% strength in PGMEA),

28.99 pbw of PGME and

0.01 pbw of silicone oil.

A substrate material according to Example 1 was coated as described there and exposed imagewise to IR radiation. A radiant energy of 250 mJ/cm² is sufficient for obtaining a fog-free image. The resistance to the developer was substantially improved. More than 50,000 satisfactory prints could be produced using the printing plate thus obtained.

### EXAMPLE 5

A coating dispersion was prepared from

8.50 pbw of carbon black dispersion having the composition stated below,

11.00 pbw of creso/xylenol/formaldehyde novolak (®Alnovol SPN 400, 45.3% strength in PGMEA),

0.40 pbw of benzophenone,

0.01 pbw of silicone oil,

49.99 pbw of PGME and

30.00 pbw of tetrahydrofuran.

The carbon black dispersion comprised

5.00 pbw of carbon black (special black 250),

66.00 pbw of cresol/xylenol/formaldehyde novolak (®Alnovol SPN 400, 45.3% strength in PGMEA),

28.99 pbw of PGME and

0.01 pbw of silicone oil.

The dispersion was applied by spin-coating to the aluminum substrate disclosed in Example 1 and was then dried. The recording material thus obtained was likewise recorded on as in Example 1. At a radiant energy of 450 mJ/cm², a fog-free image was obtained after development. The material had substantially improved resistance to the developer. More than 50,000 satisfactory prints could be produced using the printing plate obtained therefrom.

### EXAMPLE 6

A coating dispersion was prepared from

8.00 pbw of carbon black dispersion having the composition stated below,

11.58 pbw of cresol/xylenol/formaldehyde novolak (®Alnovol SPN 45.3% strength in PGMEA),

0.15 pbw of nitrocellulose (Walsroder Nitrocellulose E 330 from Wolff Walsrode AG),

0.26 pbw of poly(4-hydroxystyrene) (®Maruka Lyncur M, type S-2),

0.01 pbw of silicone oil for improving the surface structure,

54.00 pbw of PGME and

26.00 pbw of tetrahydrofuran.

The carbon black dispersion comprised

5.00 pbw of carbon black (special black 250),

66.00 pbw of cresol/xylenol/formaldehyde novolak (®Alnovol SPN 400, 45.3% strength in PGMEA),

28.99 pbw of PGME and

0.01 pbw of silicone oil.

The dispersion was applied by spin-coating to the aluminum substrate disclosed in Example 1 and was then dried. The recording material thus obtained was likewise recorded on as in Example 1. At a radiant energy of 250 mJ/cm², a fog-free image was obtained after development. The material had substantially improved resistance to the developer. More than 50,000 satisfactory prints could be produced using the printing plate obtained therefrom.

### EXAMPLE 7

A coating dispersion was prepared from

34.00 pbw of carbon black dispersion (as described in Example 4),

6.70 pbw of poly(4-hydroxystyrene), in which 30% of the hydroxyl groups had been converted into tert-butoxycarbonyloxy groups and 15% into 2,3-dihydroxypropoxy groups (for preparation, cf. EP-A 683 435),

0.01 pbw of silicone oil,

42.00 pbw of PGME and

34.00 pbw of tetrahydrofuran.

Analogously to Example 1, the coating dispersion was then applied by spin coating to an aluminum substrate according to Example 1 and was dried. The weight of the dried layer was 2 g/m².

After the recording with IR radiation, the recording material was developed for 1 min at 28° C. in a developer comprising

5.5 pbw of sodium silicate nonahydrate,

3.4 pbw of trisodium phosphate dodecahydrate,

0.4 pbw of monosodium phosphate (anhydrous) and

90.7 pbw of demineralized water.

The tonal range of the printing plate thus produced was 2 to 98% of a 60- line screen.

### EXAMPLES 8-14

Examples 1 to 7 were repeated with the difference that a 7% solution of a polyvinyl alcohol (88% hydrolyzed, 12% of the hydroxyl groups are still acetylated; viscosity 4 mPa s, measured in a 4% strength aqueous solution; ®Mowiol 4-88 from Hoechst AG) was also applied to the radiation-sensitive layer by spin-coating. cAfter drying for 2 min at 100° C., the thickness of the top layer thus produced was 1 to 3 μm. The imagewise IR exposure was carried out practically in the same way as for the recording materials without a top layer, and only a slightly higher laser power was required. The development time had to be increased by about 20% in order to obtain a comparable printing plate in each case.

German Application 197 39 302.0 filed Sep. 8, 1997, the priority document of the present application, is hereby incorporated by reference in its entirety.

Although only a few exemplary embodiments of this invention have been described in detail above, those skilled in the art will readily appreciate that many modifications are possible in the exemplary embodiments without materially departing from the teachings and advantages of this invention. Accordingly, all such modifications are intended to be included within the scope of this invention.

We claim:

1. A positive-working infrared-sensitive mixture which comprises
(i) a binder which is insoluble in water but soluble or at least swellable in aqueous alkali; and
(ii) carbon black particles dispersed in the binder,
wherein the dispersed carbon black particles function as a radiation-sensitive component for imagewise differentiation.

2. A mixture as claimed in claim 1, wherein the carbon black particles have a mean primary particle diameter of from 10 to 220 nm.

3. A mixture as claimed in claim 1, wherein the BET surface area of the carbon black particles is from 5 to 500 m²/g.

4. A mixture as claimed in claim 1, wherein the amount of the carbon black particles is from 1 to 50% by weight, based on the total weight of the nonvolatile components of the mixture.

5. A mixture as claimed in claim 1, wherein the binder contains acidic groups having a pKₐ value of less than 13.

6. A mixture as claimed in claim 5, wherein the binder comprises a polycondensate of a phenol or sulfamoyl- or carbamoyl-substituted aromatic with an aldehyde or ketone, a reaction product of a diisocyanate with a diol or diamine, provided that it has acidic groups having a pKₐ value of less than 13; or a polymer having units of a vinylaromatic, N-aryl (meth)acrylamide, or aryl (meth)acrylate, said units each also containing one or more carboxyl groups, phenolic hydroxyl groups, sulfamoyl groups, or carbamoyl groups.

7. A mixture as claimed in claim 1, wherein the binder comprises a novolak.

8. A mixture as claimed in claim 1, wherein the amount of the binder is from 50 to 99% by weight, based on the total weight of the nonvolatile components of the mixture.

9. A mixture as claimed in claim 1, which additionally contains at least one compound which increases the mixture's resistance to aqueous alkaline developers or processing chemicals.

10. A mixture as claimed in claim 9, wherein said compound which serves for increasing the resistance comprises a ketone, a quinone, an indenone, a chromen-4-one, xanthone, Meldrum's acid, a sulfone, a sulfonic acid ester, a polyphthalaldehyde, nitrocellulose, polyethylene glycol, polypropylene glycol, a poly(4-hydroxystyrene) having protected hydroxyl groups, or a poly(meth)acrylate.

11. A mixture as claimed in claim 1, which additionally contains at least one compound which controls the rate of development.

12. A mixture as claimed in claim 11, wherein the compound which controls the rate of development comprises a polyhydroxyaromatic, an aromatic mono-, di- or polycarboxylic acid, an aliphatic di- or polycarboxylic acid, a sulfonic acid, a compound having an N—H acidic group, or a polymer having an acid number of more than 100.

13. A recording material having a substrate and a radiation-sensitive layer, wherein the layer is formed from a mixture as claimed in claim 1.

14. A recording material as claimed in claim 13, wherein a top layer comprising at least one water-soluble polymeric binder, is present on the radiation-sensitive layer.

15. A recording material as claimed in claim 14, wherein the water-soluble polymeric binder comprises one or more of polyvinyl alcohol, polyvinyl-pyrrolidone, partially hydrolyzed polyvinyl acetate, gelatine, a carbohydrate, or hydroxyethylcellulose.

16. A recording material as claimed in claim 13, wherein the substrate comprises an aluminum foil or sheet; or a laminate of an aluminum foil and a polyester film.

17. A process for the production of a printing plate for offset printing, comprising exposing a recording material as claimed in claim 13 imagewise to infrared radiation, and then developing the exposed material in an aqueous alkaline developer at a temperature of from 20 to 40° C.

18. A mixture as claimed in claim 1, which does not contain any UV/VIS-sensitive components.

19. A mixture as claimed in claim 1, which does not contain components which under the action of UV/VIS radiation cause a change in the solubility of the mixture of a layer produced from the mixture.

20. A mixture as claimed in claim 1, wherein the carbon black particles are the only constituents of the mixture that gives rise to imagewise differentiation.

21. A mixture as claimed in claim, which comprises an additional infrared absorber present in an amount such that it would not be capable alone of effecting imagewise differentiation sufficient for providing a recording material.
